(19) United States
(12) Patent Application Publication
(10) Pub. No.: US 2025/0351598 A1
(43) Pub. Date: Nov. 13, 2025

(54) SEMICONDUCTOR DEVICES AND METHODS OF MANUFACTURING SEMICONDUCTOR DEVICES

(71) Applicant: Amkor Technology Singapore Holding Pte. Ltd.

(72) Inventors: Weilung Lu, Tempe, AZ (US); Adrian Arcedera, Chandler, AZ (US); Pedro Joel Rivera-Marty, Chandler, AZ (US); Lawrence Natan, Chandler, AZ (US); Remrose Manuel, Cavite (PH)

(73) Assignee: Amkor Technology Singapore Holding Pte. Ltd., (omitted)

(21) Appl. No.: 19/017,149

(22) Filed: Jan. 10, 2025

Related U.S. Application Data
(60) Provisional application No. 63/646,437, filed on May 13, 2024.
(60) Provisional application No. 63/646,484, filed on May 13, 2024.

(51) Int. Cl. H10F 39/00; H01L 25/16; H10F 39/95

(52) U.S. Cl. CPC H10F 39/804; H01L 25/167; H10F 39/024; H10F 39/8063; H10F 39/95

(57) ABSTRACT

In one example, an electronic device comprises a substrate including a cavity defined in an upper side of the substrate. An electronic component can be disposed over the substrate, and a lid can be disposed over the substrate and including a lid stopper in the cavity. A pedestal of the lid can be positioned over the electronic component. The lid can include a channel adjacent the pedestal. A lens can be disposed over the electronic component and on the pedestal. Other examples and related methods are also disclosed herein.

### CROSS-REFERENCE TO RELATED APPLICATIONS

This application claims priority to U.S. Provisional Patent Application No. 63/646,437 filed on May 13, 2024, and entitled “SEMICONDUCTOR DEVICES AND METHODS OF MANUFACTURING SEMICONDUCTOR DEVICES,” and to U.S. Provisional Patent Application No. 63/646,484 filed on May 13, 2024 and entitled “SEMICONDUCTOR DEVICES AND METHODS OF MANUFACTURING SEMICONDUCTOR DEVICES,” both of which are incorporated herein by reference.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2G show an example method for manufacturing an electronic device using cross-sectional views.

FIGS. 3A to 3C show perspective views of an example electronic device.

FIGS. 4A to 4E show an example method for manufacturing an electronic device using cross-sectional views.

FIG. 5 shows a cross-sectional view of an example electronic device.

FIG. 6 shows a cross-sectional view of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence or addition of one or more other features.

The terms “first,” “second,” etc. may be used herein to describe various elements, and the elements described using first, second, etc. should not be limited by these terms. The terms “first,” “second,” etc. are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical or mechanical coupling.

### DESCRIPTION

An example electronic device comprises a substrate including a cavity defined in an upper side of the substrate. An electronic component can be disposed over the substrate, and a lid can be disposed over the substrate and including a lid stopper in the cavity. A pedestal can be positioned over the electronic component, and a channel can be adjacent the pedestal. A lens can be disposed over the electronic component and on the pedestal.

An example method of manufacturing an electronic device comprises the step of providing a lid including a stopper on a lower side of the lid. A pedestal can have an upper side oriented away from the lower side of the lid, and a channel can be located adjacent the pedestal. A first adhesive can be disposed in the channel. A lens can be provided over the first adhesive and can contact the pedestal. An electronic component can be coupled to an upper side of a substrate. The lid can be disposed over the substrate. The stopper can be located in a cavity formed in the upper side of the substrate, and the lens can be over the electronic component.

Another example electronic device can comprise a substrate. An electronic component can be disposed over the substrate. The electronic component can include a sensor region oriented away from the substrate. A body can be disposed over the substrate and around the electronic component, the body comprising a pedestal and a channel adjacent the pedestal. The sensor region of the electronic component can be exposed from the body. A lens can be disposed over the electronic component and on the pedestal.

Other examples are included in the present disclosure. Such examples may be found in the figures, in the claims, or in the description of the present disclosure.

Electronic devices of the present disclosure can include a liquid-crystal-polymer (LCP) lid defining a channel between a pedestal and a lid sidewall. The pedestal can include an upper side configured to receive or contact a lens. The upper side of the pedestal can be sized and made to locate the lens at a desired distance above a sensor of an application-specific integrated circuit (ASIC). The pedestal can thus function as a stand-off or distance control. An adhesive can be disposed in and can fill the channel adjacent the pedestal. The adhesive can contact the lid and the lens to retain the lens in place over the ASIC sensor.

In various embodiments, the LCP lid can also contact an underlying substrate. A notch defined by a sidewall of the LCP lid and a cavity provided in an upper side of the substrate can be adjacent one another and can define a space or volume configured to receive adhesive material. By contacting the substrate, the LCP lid can position the upper side of the pedestal at a desired distance from the substrate. The LCP lid of the present disclosure can thus position the lens with increased accuracy and precision.

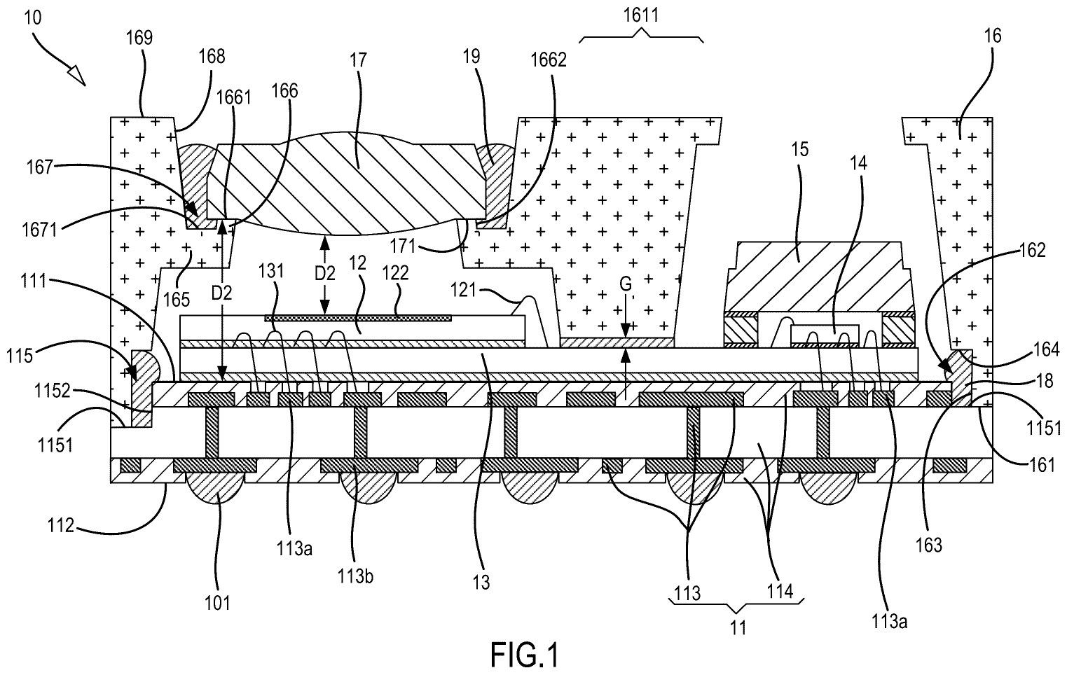

FIG. 1 shows an example electronic device 10. In accordance with various examples, electronic device 10 can include a substrate 11, electronic component 12, electronic component 13, electronic component 14, component 15, lid 16, and lens 17. Electronic components 12, 13, and 14 can be coupled to substrate 11. In some examples, electronic component 12, electronic component 14, or component 15 can be coupled to electronic component 13. Lid 16 can be coupled to substrate 11 via a lid adhesive 18. Lens 17 can be coupled to lid 16 via a lens adhesive 19. substrate 11.

In accordance with various examples, substrate 11 comprises inner (or upper) side 111, outer (or lower) side 112, conductive structure 113, and dielectric structure 114. Conductive structure 113 can include inner terminals 113a located at or exposed from upper side 111, and outer terminals 113b located at or exposed from outer side 112. Electronic component 13 can be coupled to upper side 111 of substrate 11. In some examples, interconnects 131 can be coupled between electronic component 13 and inner terminals 113a of substrate 11. Interconnects 131 can electrically couple electronic component 13 to conductive structure 113. In some examples, interconnects 121 can electrically couple electronic component 12 to electronic component 13. In some examples, electronic component 12 can include sensor region 122. Sensor region 122 can be oriented toward lens 17.

In some examples, electronic device 10 can include external interconnects 101. External interconnects 101 can be coupled to outer terminals 113b of conductive structure 113. In some examples, electronic device 10 can be a land grid array (LGA). For example, electronic device 10 can be devoid of external interconnects 101, and outer terminals 113b can be configured to connect electronic device 10 to a substrate (e.g., to a PCB).

In accordance with various examples, substrate 11 includes cavity 115. Cavity 115 can be formed in upper side 111 of substrate 11. Cavity 115 can be defined by a floor (or recessed side) 1151 and sidewall 1152. Sidewall 1152 can extend between floor 1151 and upper side 111. Floor 1151 can be lower (i.e., on a different horizontal plane) than upper side 111 to define cavity 115 in substrate 11.

Lid 16 can be coupled to substrate 11. In some examples, lid 16 can comprise an LCP lid. A lower side or stopper 161 of lid 16 contacts (e.g., bottoms out against or abuts) floor 1151 of cavity 115. Stopper 161 can also be referred to as a standoff, leg, or downward protrusion of lid 16. Lid 16 can include notch 162. Notch 162 can be adjacent stopper 161. Notch 162 can be defined by a sidewall 163 and horizontal surface 164 of lid 16. Sidewall 163 can extend from stopper 161 to horizontal surface 164. Horizontal surface 164 can be generally parallel to stopper 161. As used herein, “generally parallel” means ±15° from parallel. Sidewall 163 of notch 162 can be oriented toward sidewall 1152 of cavity 115. Cavity 115 in substrate 11 and notch 162 in lid 16 can provide or define an adhesive region (e.g., a cavity, basin, volume, or corner) to receive lid adhesive 18 in the area adjacent to stopper 161.

In various examples, lid 16 comprises an arm 165 extending laterally over substrate 11. In some examples, arm 165 can vertically overlap (i.e., overlap in a vertical direction that is orthogonal to upper side 111 of substrate 11), at least, a portion of electronic component 12 and/or electronic component 13. Lid 16 comprises a pedestal 166 configured to receive lens 17. Pedestal 166 can extend, or protrude, from arm 165 away from upper side 111 of substrate 11. Lens 17 can contact a mating surface or upper side 1661 of pedestal 166. Lens 17 can contact upper side 1661 of pedestal 166 along contact area 171 of lens 17. Lens 17 can bottom out or abut against (e.g., directly contact) pedestal 166 of lid 16. A channel 167 in lid 16 can be adjacent pedestal 116. Channel 167 can be defined by channel floor 1671, pedestal sidewall 1662, and lid sidewall 168. Channel floor 1671 can extend between pedestal sidewall 1662 and lid sidewall 168. Pedestal sidewall 1662 can extend between channel floor 1671 and upper side 1661 of pedestal 166. Lid sidewall 168 can extend between channel floor 1671 and an upper side 169 of lid 16. Channel 167 can be configured to receive and retain lens adhesive 19. In some examples, channel 167 can comprise or be referred to as an adhesive basin. Lens adhesive 19 can generally fill channel 167. Lens adhesive 19 can contact a lateral side of lens 17 and a lower side of lens 17 outside lid contact area 171. Lens adhesive 19 can also contact lid sidewall 168 and pedestal sidewall 1662.

In accordance with various examples, the vertical position of stopper 161 can be controlled to position features of lid 16 (e.g., pedestal 166) and lens 17 at desired heights over substrate 11 and electronic components 12 and 13. For example, stopper 161 abutting floor 1151 and lens 17 contacting pedestal 166 can allow for precise control of a distance D1 between upper side 1661 of pedestal 166 and upper side 111 of substrate 11 and a distance D2 between lens 17 and sensor region 122. Contact between lid 16 and substrate 11 and between lid 16 and lens 17 can improve the precision with which lens 17 is positioned above electronic components 12, 13 and substrate 11. Electronic device 10 can have reduced manufacturing tolerances between substrate 11 and lid 16 and between lid 16 and lens 17, which improves the precision with which lens 17 can be vertically located. Contact between stopper 161 of lid 16 and floor 1151 of substrate cavity 115 can additionally maintain a small gap G defined between electronic component 13 and a central portion 1611 of lid 16. Maintaining gap G can reduce crushing or other damage stemming from contact of electronic component 13 by central portion 1611 of lid 16 and can improve light isolation between components (e.g., between electronic component 12 and electronic component 14). Central portion 1611 of lid 16 can refer to the portion of lid 16 that is disposed generally between electronic component 12 and electronic component 14.

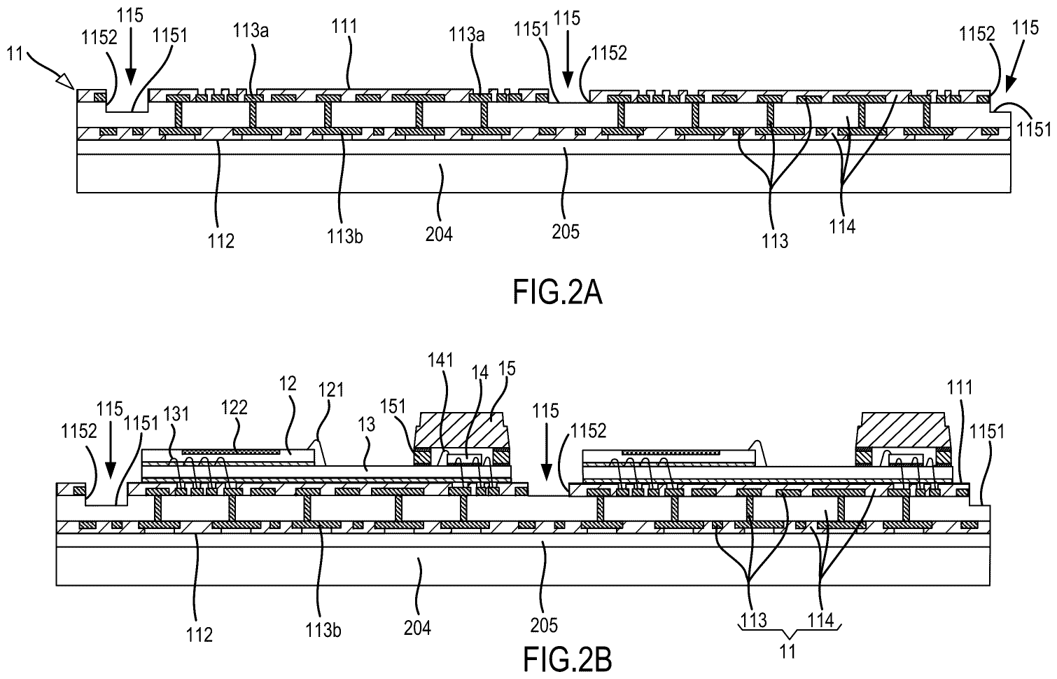

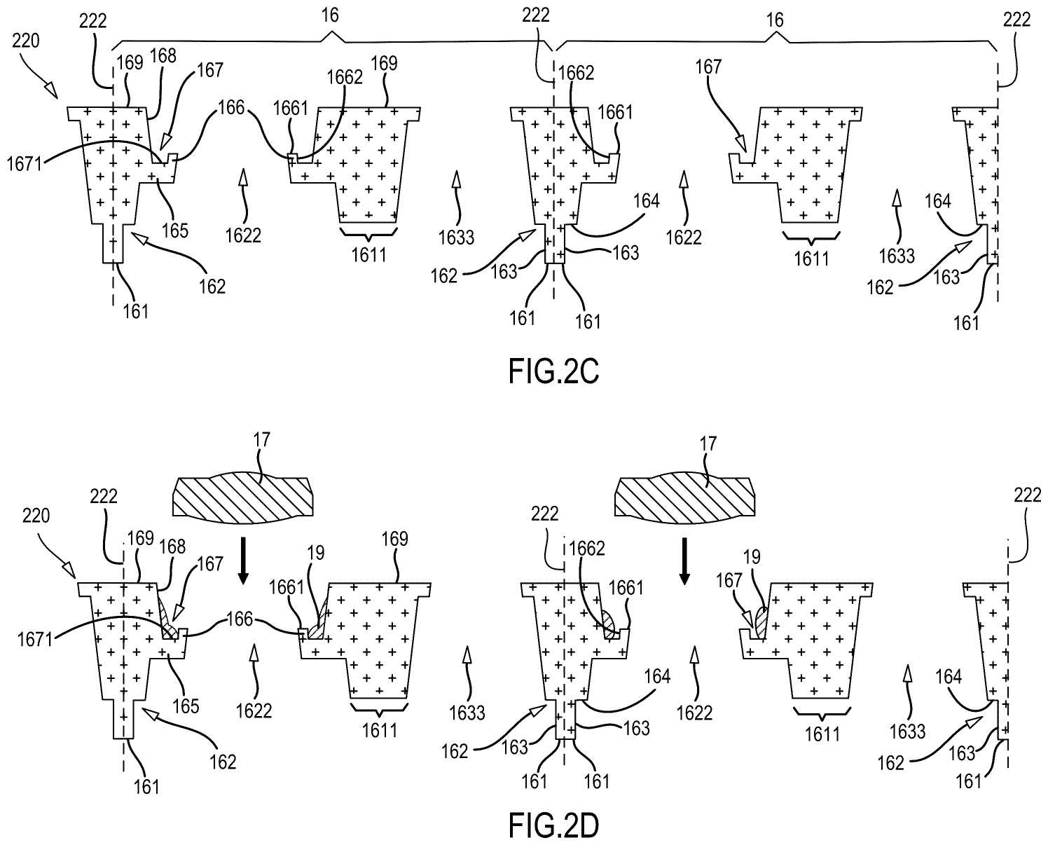

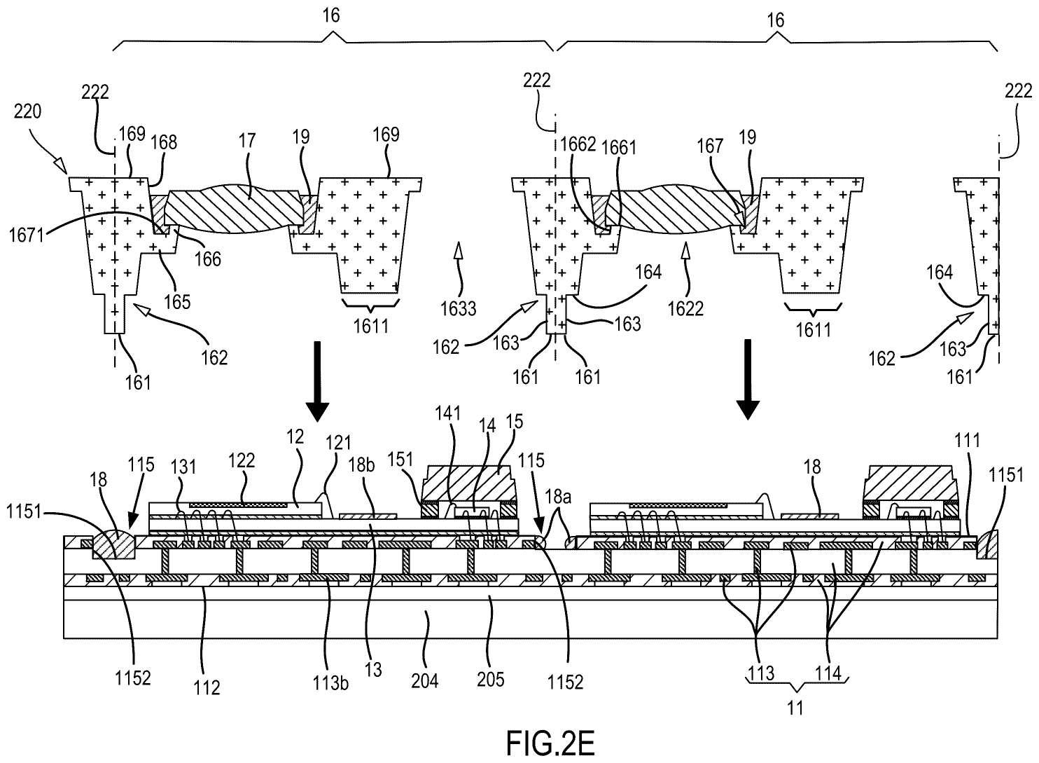

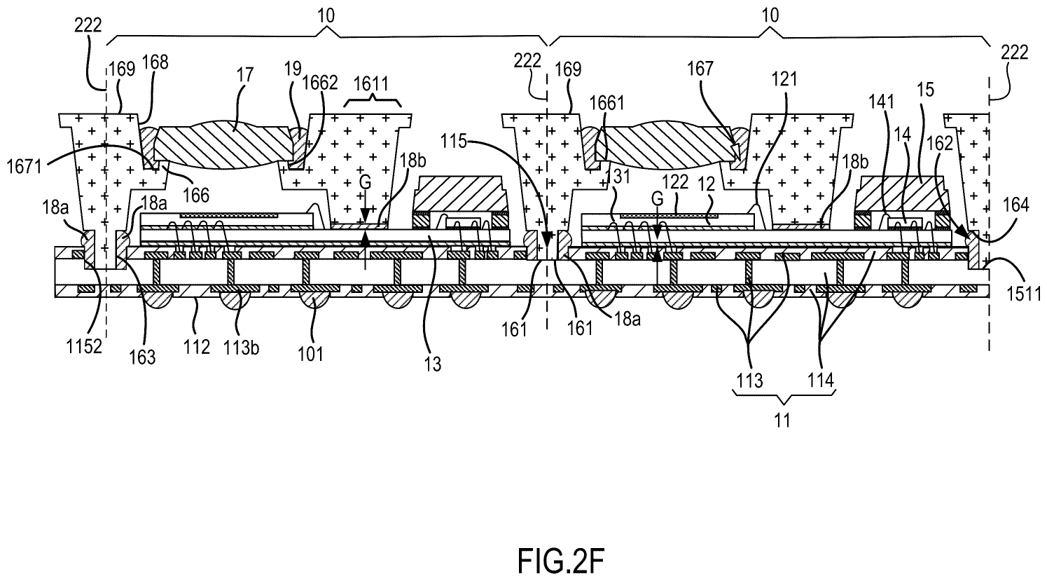

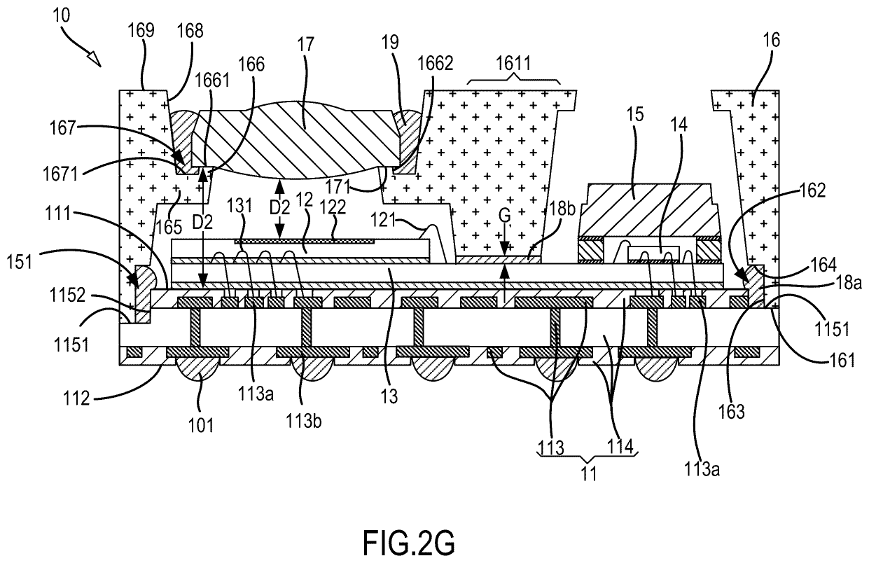

With reference to FIGS. 2A-2G, an example method of manufacturing an electronic device 10 is shown, in accordance with various examples.

FIG. 2A shows example electronic device 10 at an early stage of manufacture. In the example of FIG. 2A, substrate 11 is provided. Substrate 11 can include upper side 111 and lower side 112 opposite upper side 111. Cavities 115 can be provided in upper side 111. Cavities 115 can each include floor 1151 and sidewall 1152. Cavities 115 are configured to receive a bottom side of lid 16 (FIG. 1) in a later stage of manufacture. Floor 1151, defining the width of cavity 115, can have a width of approximately 250 micrometers (μm) to approximately 1,400 μm, approximately 300 μm to approximately 1,000 μm, or approximately 500 μm to approximately 850 μm, in some examples. As used herein with reference to measurements of length, approximately can mean +/−5%, +/−10%, +/−15%, +/−20%, or +/−25%. Measurements are disclosed herein as examples for purposes of illustration and are intended to be nonlimiting. Cavities 115 can be sawed through at a later stage of manufacture (e.g., during singulation) to provide individual electronic devices 10. In some examples, after singulation, floor 1151 can have a width between approximately 125 μm and approximately 700 μm, approximately 150 μm and approximately 500 μm, or approximately 250 μm and approximately 425 μm.

In some examples, substrate 11 can be provided on a carrier 204. Carrier 204 can be a substantially planar plate, board, wafer, panel, or strip. Carrier 204 can be made of metal, ceramic, glass, or wafer material (e.g., a semiconductor material). In some examples, the thickness of carrier 204 can range from approximately 300 μm to 2000 μm, and the width of carrier 204 can range from approximately 100 millimeters (mm) to 300 mm. In some examples, carrier 204 can have a width up to 600 mm. Carrier 204 serves to support and enable handling of multiple components during a process of providing electronic devices 10. In some examples, carrier 204 can comprise a temporary bond layer 205 between the upper side of carrier 204 and lower side 112 of substrate 11. For example, temporary bond layer 205 can be a heat release tape or film or an optical release tape or film, where an adhesive strength of temporary bond layer 205 can be weakened or removed by application of heat or light, respectively. In some examples, the adhesive strength of temporary bond layer 205 can be weakened or removed by chemical force.

In accordance with various examples, substrate 11 comprises dielectric structure 114 and conductive structure 113. In some examples, dielectric structure 114 can comprise or be referred to as one or more stacked dielectric layers. For instance, the one or more dielectric layers can comprise, one or more core layers, polymer layers, pre-preg layers, or solder mask layers stacked on each other. One or more layers or elements of conductive structure 113 can be interleaved with elements or layers of dielectric structure 114. In some examples, dielectric structure 114 can comprise FR4 (copper foil/glass fiber fabric/copper foil laminate), bismaleimide triazine (BT), polyimide (PI), benzocyclobutene (BCB), polybenzoxazole (PBO), phenolic resin, or Ajinomoto Buildup Film (ABF), mold compound, or glass. The thickness of individual layers of dielectric structure 114 can range from approximately 20 μm to approximately 1400 μm. In some examples, a core of dielectric structure 114 can have thickness of between approximately 100 μm and approximately 1400 μm, between approximately 200 μm and 1250 μm, between approximately 400 μm and 800 μm, of approximately 200 μm, of approximately 820 μm, or of approximately 1250 μm. In some examples, individual layers of dielectric structure 114 (e.g., ABF layers) can be laminated to the core structure and/or to one another. The laminated layers of dielectric structure 114 can each have a thickness between approximately 10 μm and approximately 50 μm, between approximately 25 μm and approximately 40 μm, between approximately 25 μm and approximately 35 μm, of approximately 20 μm, of approximately 25 um, or of approximately 33 μm. In some examples, the outermost dielectric layer on each of upper side 111 and lower side 112 can comprise a solder resist material, which in some examples, can be different from the material of the laminated layers and the core. In some examples, the solder resist layers can be provided by screen printing and can have a thickness of between approximately 10 μm and approximately 50 μm, between approximately 20 μm and approximately 40 μm, between approximately 20 μm and approximately 30 μm, of approximately 20 μm, or of approximately 22 μm. In some examples, the thickness of the solder resist layer can be less than the thickness of the individual laminated layer(s). The combined thickness of the layers of dielectric structure 114 can define the thickness of substrate 11. Dielectric structure 114 can maintain the shape of substrate 11 and can structurally support conductive structure 113.

In some examples, cavities 115 can extend to or into the core of dielectric structure 114, such that the core of dielectric structure 114 forms floor 1151. In some examples, cavities 115 can extend partially through the laminated layer(s) of dielectric structure 114, such that at least a portion of the laminated dielectric layer(s) remains between floor 1151 and the core of dielectric structure 114. In some examples, cavities 115 can extend into or through solely a solder resist layer of dielectric structure 114, such that cavities 115 do not extend into the laminated dielectric layers or the core of dielectric structure 114. In some examples, a depth of cavity 115 (i.e., a length of sidewall 1152) can be between approximately 20 μm and 850 μm, 50 μm to approximately 500 μm, 40 μm to approximately 190 μm, or approximately 45 μm to approximately 195 μm.

Conductive structure 113 can comprise or be referred to as one or more conductive layers defining signal distribution elements, traces, vias, pads, under bump metallization (UBM), redistribution layers (RDLs), conductive patterns, conductive paths, wiring patterns, or circuit patterns. In some examples, conductive structure 113 can comprise one or more layers of copper (Cu), aluminum (Al), tin (Sn), titanium (Ti), titanium tungsten (TiW), gold (Au), silver (Ag), nickel (Ni), palladium (Pd), or combinations or alloys thereof. The thickness of conductive structure 113 can be from approximately 5 μm to approximately 50 μm, 10 μm to approximately 30 μm, 15 μm to approximately 25 μm, or 18 μm to approximately 20 μm. The thickness of conductive structure 113 can refer to individual layers of conductive structure 113. In some examples, conductive structure can have a trace width and trace spacing (width/spacing) of between approximately 5 μm/5 μm and approximately 50 μm/50 μm, between approximately 8 μm/8 μm and approximately 40 μm/40 μm, between approximately 9 μm/12 μm and approximately 25 μm/25 μm, or between approximately 9 μm/12 μm and approximately 20 μm/20 μm. Trace width is the width of individual traces of conductive structure 113 and trace spacing is the distance between adjacent traces of conductive structure 113. Conductive structure 113 provides electrical signal paths (e.g., vertical paths and horizontal paths) through dielectric structure 114.

Conductive structure 113 can comprise inner terminals 113a provided along upper side 111 of substrate 11, and outer terminals 113b provided along outer side 112 of substrate 11. In some examples, inner terminals 113a and outer terminals 113b can comprise or be referred to as pads, lands, or UBM. Layers and elements of conductive structure 113 can electrically couple inner terminals 113a with outer terminals 113b.

Substrate 11 can comprise a core or be coreless. In some examples, substrate 11 can comprise or be referred to as pre-formed or laminate substrate. In some examples, substrate 11 can comprise or be referred to as a build-up or RDL substrate. In some examples, substrate 11 can have a thickness of between approximately 0.2 mm and approximately 4 mm, between approximately 0.3 mm and approximately 2.0 mm, or between approximately 0.4 mm and approximately 1.6 mm.

It is contemplated and understood that one or more layers or elements of conductive structure 113 can be interleaved with dielectric structure 114 and that dielectric structure 114 and conductive structure 113 can each include any number of layers in substrate 11. Inner terminals 113a and outer terminals 113b can be provided to be spaced apart from each other in rows and columns on opposing sides of substrate 11.

In some examples, substrate 11 can be a pre-formed or laminate substrate. Pre-formed substrates can be manufactured prior to attachment to an electronic component (or prior to disposal over carrier 204) and can comprise dielectric layers between respective conductive layers. The conductive layers can comprise copper and can be formed using an electroplating process. The dielectric layers can be relatively thicker non-photo-definable layers that can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a glass or dielectric material comprising BT or FR4, and dielectric and conductive layers can be formed on the permanent core structure. In other examples, the pre-formed substrate can be a coreless substrate and omit the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrates can be formed through a semi-additive or modified-semi-additive process.

In some examples, substrate 11 can be a redistribution layer (“RDL”) substrate. RDL substrates can comprise one or more conductive redistribution layers and one or more dielectric layers. A RDL substrate can include multiple units of redistribution structure suitable for singulation during creation of electronic device 10. RDL substrates can be formed layer by layer over an electronic component to where the RDL substrate is to be coupled. RDL substrates can be formed layer by layer over a carrier and can be entirely or partially removed after an electronic component is coupled to the RDL substrate. RDL substrates can be manufactured layer by layer as a wafer-level substrate on a round wafer in a wafer-level process, or as a panel-level substrate on a rectangular or square panel carrier in a panel-level process.

RDL substrates can be formed in an additive buildup process and can include one or more dielectric layers alternatingly stacked with one or more conductive layers and define respective conductive redistribution patterns or traces configured to collectively fan-out electrical traces outside the footprint of the electronic component, or to fan-in electrical traces within the footprint of the electronic component. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask.

The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and can interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layers can comprise silicon nitride (Si3N4), silicon oxide (SiO2), or silicon oxynitride (SiON). The inorganic dielectric layers can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising BT or FR4, and these types of RDL substrates can comprise or be referred to as a coreless substrate. In accordance with various examples, substrates in this disclosure can comprise pre-formed (e.g., laminate) substrates or RDL substrates.

FIG. 2B shows example electronic device 10 at a later stage of manufacture. In the example of FIG. 2B, electronic component 12, electronic component 13, electronic component 14, and component 15 can be coupled to upper side 111 of substrate 11. Electronic component 12, electronic component 13, and electronic component 14 can comprise semiconductor die, semiconductor chips, or packages (e.g., one or more encapsulated semiconductor die coupled to an interposer or substrate). For example, one or more of electronic component 12, electronic component 13, electronic component 14 can comprise an integrated circuit die separated from a semiconductor wafer having multiple die. In some examples, electronic component 12, electronic component 13, and/or electronic component 14 can comprise a DSP (digital signal processor), a network processor, a power management unit, an audio processor, a RF (radio-frequency) circuit, a wireless baseband SoC (system-on-chip) processor, a sensor, or an ASIC (application specific integrated circuit). One or more of electronic components 12, 13, or 14 can be configured to perform calculation and control processing, store data, remove noise from electrical signals, or perform other electronic functions.

In accordance with various examples, electronic device 10 can comprise an optical device. In some examples, electronic component 12 can comprise a sensor ASIC, having a sensor region 122, and electronic component 13 can comprise a driver ASIC. Electronic component 12 can be coupled to electronic component 13 and can be in electronic communication with electronic component 13 via interconnects 121. Interconnects 121 can comprise wire bonds or other suitable interconnect structure. Electronic component 13 can be coupled to upper side 111 of substrate 11 and can be in electronic communication with conductive structure 113 via interconnects 131. For examples, interconnects 131 can be coupled to inner terminals 113a of conductive structure 113. Interconnects 131 can comprise wire bonds or other interconnect structure (e.g., bumps).

Component 15 and electronic component 14 can be coupled to an upper side of electronic component 13. In some examples, electronic component 14 can comprise a light source and component 15 can comprise a micro lens array (MLA) and can be disposed over electronic component 14. For example, electronic component 14 can comprise a vertical-cavity surface-emitting laser (VCSEL). Component 15 can be coupled to electronic component 13 via standoffs 151. Standoffs 151 can create vertical distance between component 15 and the upper side of electronic component 13. Adhesive or other bonding material can be employed to couple standoffs 151 to electronic component 14 and component 15. In some examples, electronic component 14 can be coupled to electronic component 13 and can be and in electronic communication with electronic component 13 via interconnects 141. Interconnects 141 can comprise wire bonds or other suitable interconnect structure (e.g., bumps). In some examples, electronic component 14 can be electrically coupled to or in communication with electronic component 12 via electronic component 13 or substrate 11. While component 15 and electronic component 14 are shown as coupled to an upper side of electronic component 13, it is contemplated and understood that, in some examples, component 15 and electronic component 14 can be coupled to upper side 111 of substrate 11.

FIG. 2C shows example lid 16 of electronic device 10 at a different stage of manufacture. In the example of FIG. 2C, lid structure 220 is provided and comprises multiple lids 16. Lids 16 can be aligned in rows, columns, or array arrangements in lid structure 220. Lid structure 220 can be formed by molding a moldable material and can be referred to as a molded structure. Moldable materials can include, for example, plastics, polymers (e.g., LCP), acrylonitrile butadiene styrene (ABS), or other moldable materials having suitable dimensional stability. Molded structures of lid structure 220 and of lids 16 can have tolerances of approximately +/−30 μm, +/−40 μm, +/−50 μm, or +/−60 μm.

In accordance with various examples, a lower side of lid 16 includes stopper 161. In some examples, stopper 161 can extend continuously around a perimeter of each individual lid 16 once lid structure 220 is sawn through saw line or saw street 222. Notch 162 can be provided in lid 16 adjacent stopper 161. Sidewall 163 and horizontal surface 164 of lid 16 define notch 162. In some examples, a distance between stopper 161 and horizontal surface 164 (e.g., the length of sidewall 163) can be approximately 30 μm to approximately 900 μm, 50 μm to approximately 600 μm, 100 μm to approximately 250 μm, or approximately 50 μm to approximately 200 μm. In some examples, after singulation along saw street 222, stopper 161 can have a width of approximately 50 μm to approximately 200 μm.

In accordance with various examples, the lower side of lid 16 in central portion 1611 of lid 16 can be elevated relative to the lower side at stopper 161. For example, the lower side of lid 16 in central portion 1611 can reside on a different horizontal plane relative to the horizontal plane on which the lower side of lid 16 at stopper 161 resides. In some examples, vents or openings can be defined between segments of stoppers 161, which can be intermittent, segmented, or spaced around the perimeter of lid 16. For example, the vents can extend from sidewall 163 to the exterior lateral side of lid 16.

In accordance with various examples, lid 16 further comprises laterally extending arm 165. Pedestal 166 of lid 16 extends vertically from arm 165. Upper side 1661 of pedestal 166 is oriented away from stopper 161. Pedestal 116 defines a portion of channel 167. For example, channel 167 can be defined by channel floor 1671, pedestal sidewall 1662, and lid sidewall 168. Channel floor 1671 can extend between pedestal sidewall 1662 and lid sidewall 168. Pedestal sidewall 1662 can extend between channel floor 1671 and upper side 1661 of pedestal 166. Lid sidewall 168 can extend between channel floor 1671 and upper side 169 of lid 16. Pedestal 166 can have a height of approximately 25 μm to approximately 400 μm, approximately 50 μm to approximately 200 μm, or approximately 75 μm to approximately 125 μm. For example, distance between channel floor 1671 and upper side 1661 of pedestal 166 (i.e., the length of pedestal sidewall 1662) can be approximately 25 μm to approximately 400 μm, approximately 50 μm to approximately 200 μm, or approximately 75 μm to approximately 125 μm. In some examples, upper side 1661 of pedestal 166 can be approximately 25 μm to approximately 400 μm, approximately 50 μm to approximately 200 μm, or approximately 75 μm to approximately 125 μm. In some examples, pedestal 166 can extend continuously around an inner perimeter defining an opening 1622. Lid 16 can also include an opening 1633. Central portion 1611 of lid 16 can be between opening 1622 and opening 1633. In some examples, vents can be defined between segments of pedestal 166. The vents can be intermittent, segmented, or spaced around the inner perimeter defining opening 1622. For example, the vents can extend between opening 1622 and pedestal sidewall 1662.

FIG. 2D shows example electronic device 10 at a later stage of manufacture. In the example of FIG. 2D, lenses 17 can be provided on lids 16. In some examples, lens 17 can be coupled to lid 16 by lens adhesive 19. Lens adhesive 19 can comprise an adhesive, film, or epoxy. In some examples, lens adhesive 19 can be provided in channel 167. Lens adhesive 19 can contact lid sidewall 168, channel floor 1671, and pedestal sidewall 1662. In some examples, lens adhesive 19 can be deposited as one or more bead(s) on lid sidewall 168 and can be spaced apart from pedestal sidewall 1662 prior to attachment of lens 17.

FIG. 2E shows example electronic device 10 at a later stage of manufacture. In the example of FIG. 2E, lens 17 is coupled to lid 16, and lid structure 220, having lenses 17 coupled to lids 16, is provided over substrate 11. Lens 17 can be coupled to lid 16 with lens adhesive 19 substantially filling channel 167. In some examples, lens 17 can be pressed into lens adhesive 19 and can urge lens adhesive 19 to fill channel 167 and translate towards pedestal 166. Lens adhesive 19 can be coupled to and can contact a lower side of lens 17 and a sidewall of lens 17. Pedestal 166 can retain lens adhesive 19 in channel 167 and against lid sidewall 168 to limit spillage of lens adhesive 19.

In accordance with various examples, lens 17 can be seated on pedestal 166. For example, contact or interface area 171 of lens 17 contacts upper side 1661 of pedestal 166. In some examples, contact area 171 can be substantially devoid of lens adhesive 19. As used herein, the phrase “substantially devoid” of a material can mean small traces or remnant film of the material can be in the region described as “substantially devoid” of the material. Lens 17 can be coupled to lid 16 by lens adhesive 19 contacting lens 17 outside contact area 171. Because channel 167 permits lens adhesive 19 to be displaced or remain outside contact area 171, lens 17 can be positioned directly on upper side 1661 of pedestal 166 at a precisely controlled vertical distance from stopper 161 (i.e., from the lower side of lid 16 that contacts substrate 11), and also from electronic component 12 once stopper 161 is seated on floor 1151 of cavity 115 in substrate 11.

In accordance with various examples, lid 16 can be provided over substrate 11. Lid adhesive 18 can be selectively deposited on substrate 11 at locations configured to receive lid 16. For example, some lid adhesive 18, referred to herein as perimeter adhesive 18a, can be deposited in cavities 115, and some lid adhesive 18, referred to herein as central adhesive 18b, can be between central portion 1611 of lid 16 and electronic component 12. For example, central adhesive 18b can be deposited on the upper side of electronic component 12. In some examples, perimeter adhesive 18a can be deposited along sidewalls 1152 of cavities 115, such that a portion of cavity floor 1151 is devoid of perimeter adhesive 18a. A volume of perimeter adhesive 18a can be selected to limit, reduce, or prevent the flow of perimeter adhesive 18a over upper side 111 of substrate 11. Similarly, a volume of central adhesive 18b can be selected to limit, reduce, or prevent the flow of central adhesive 18b beyond a footprint of central portion 1611 of lid 16.

In accordance with various examples, lid 16 can be positioned over substrate 11 such that stoppers 161 are positioned over or vertically aligned with perimeter adhesive 18a and cavities 115, and central portion 1611 of lid 16 can be positioned over or vertically aligned with central adhesive 18b.

FIG. 2F shows example electronic device 10 at a later stage of manufacture. In the example of FIG. 2F, lid structure 220 is coupled to substrate 11. In accordance with various examples, lid structure 220 is translated toward substrate 11 until stoppers 161 contact substrate 11. In some examples, stopper 161 can be urged through perimeter adhesive 18a until stopper 161 bottoms out against floor 1151 of substrate cavity 115. In some example, perimeter adhesive 18a can migrate upward along sidewall 1152 and sidewall 163. Lid 16 can be coupled to substrate 11 by perimeter adhesive 18a contacting sidewall 163 of lid 16, cavity floor 1151, and sidewall 1152 of cavity 115. In some examples, perimeter adhesive 18a can contact horizontal surface 164 of lid 16 and/or upper side 111 of substrate 11. The length of sidewall 163 and/or horizontal surface 164 (e.g., the volume of notch 162) can be selected to reduce or prevent flow of perimeter adhesive 18a over upper side 111 of substrate 11, which can allow for substrates 11 having a smaller area (i.e., smaller footprint). In accordance with various examples, sidewalls 1152 of cavity 115 can also limit lateral translation of stopper 161, which can laterally align lid 16 over substrate 11. In accordance with various examples, stopper 161 directly contacts floor 1151 and the interface between stopper 161 and floor 1151 of cavity 115 can be substantially devoid of perimeter adhesive 18a.

In various examples, saw street 222 and stoppers 161 of lid structure 220 can be positioned in cavities 115. Saw street 222 can bisect adjacent stoppers 161. In some examples, saw street 222 can have a width of approximately 150 μm to approximately 400 μm. Each stopper 161 can have a width of approximately 25 μm to approximately 400 μm, approximately 50 μm to approximately 200 μm, or approximately 75 μm to approximately 125 μm. In this regard, saw street 222 and the two stoppers 161 located at opposing sides of saw street 222 can have a combined width from approximately 200 μm to approximately 1200 μm, approximately 250 μm to approximately 800 μm, or approximately 300 μm to approximately 650 μm. Cavity 115 can have a width greater than the combined width of saw street 222 and its adjacent stoppers 161. The greater width of cavity 115 allows for perimeter adhesive 18a to couple to or contact sidewall 163 of lid 16 and sidewall 1152 of cavity 115.

In some examples, central portion 1611 of lid 16 can be positioned on or aligned over an upper side of an electronic component 12. Central portion 1611 can be pressed into contact with central adhesive 18b. Central adhesive 18b can be in or fill gap G between central portion 1611 and the upper side of electronic component 12. Stopper 161 abutting floor 1151 allows for precise control of the vertical position of central portion 1611 over electronic component 12 (i.e., the height of gap G). Controlling and knowing the height of gap G allows for selection of a central adhesive 18b volume that can fill gap G, while minimizing or preventing central adhesive 18b from extending outside the footprint of central portion 1611 as lid 16 is pressed into position against substrate 11. In some examples, Gap G can have a height ranging from approximately 25 μm to approximately 100 μm.

In accordance with the example of FIG. 2G, carrier 204 (FIG. 2F) can be removed and external interconnects 101 can be provided on outer terminals 113b. External interconnects 101 can comprise bumps, pads, or pillars, for example.

In accordance with various examples, after providing external interconnects 101 a singulation process can be performed to separate individual electronic devices 10. The singulation process can include sawing along saw streets 222. During the singulation process, a sawing tool (e.g., diamond blade wheel, laser beam, or other cutting device) can cut through lid structure 220 and substrate 11 to separate individual electronic devices 10. After singulation, the exterior lateral sides of lid 16 and substrate 11 can be coplanar. After singulation through saw street 222, electronic device 10 may comprise stopper 161 around its outer perimeter. In some examples, an area or footprint of substrate 11 can be adjusted or selected according to the desired area of lid 16 or based on the size and/or number of electric components coupled to substrate 11. In some examples, after singulation, substrate 11 can have an area of between approximately 1 mm by 1 mm and approximately 150 mm by 150 mm.

FIG. 2G depicts an example of an individual electronic device 10 after singulation. In the example of FIG. 2G, stopper 161 can contact substrate 11 to locate lid 16 and its pedestal 166 (along with lens 17 coupled directly to pedestal 166) at a precise vertical distance D2 over substrate 11. By tightly controlling the relative positions of stopper 161 and pedestal 166, lid 16 can precisely position lens 17 at a desired distance D2 above sensor region 122 of electronic component 12. The bond line thickness (BLT) between lens 17 and pedestal 166 can be approximately zero, as the interface between contact area 171 of lens 17 and upper side 1661 of pedestal 166 can be substantially devoid of adhesive material. Similarly, the BLT between stopper 161 and substrate 11 can be zero or nearly zero, as the interface between stopper 161 and cavity floor 1151 of substrate 11 can be substantially devoid of adhesive material.

Direct contact between substrate 11 and lid 16, and between lid 16 and lens 17, reduces and can eliminate variance in lens height D2 caused by variable adhesive BLT. The reduced variance in height of lid 16 over substrate 11 and resulting tighter manufacturing tolerances allow for a smaller gap G between central portion 1611 of lid 16 and electronic component 12. The size of gap G can be reduced without causing direct contact between central portion 1611 and electronic component 12.

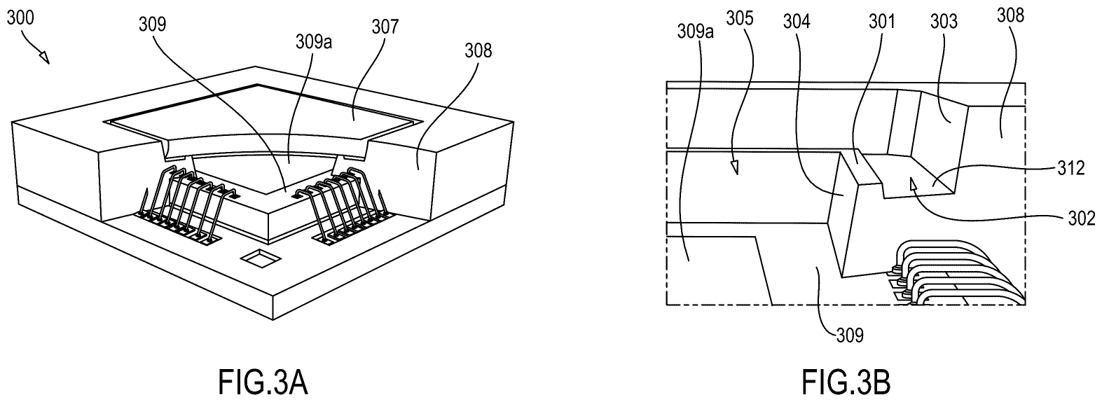

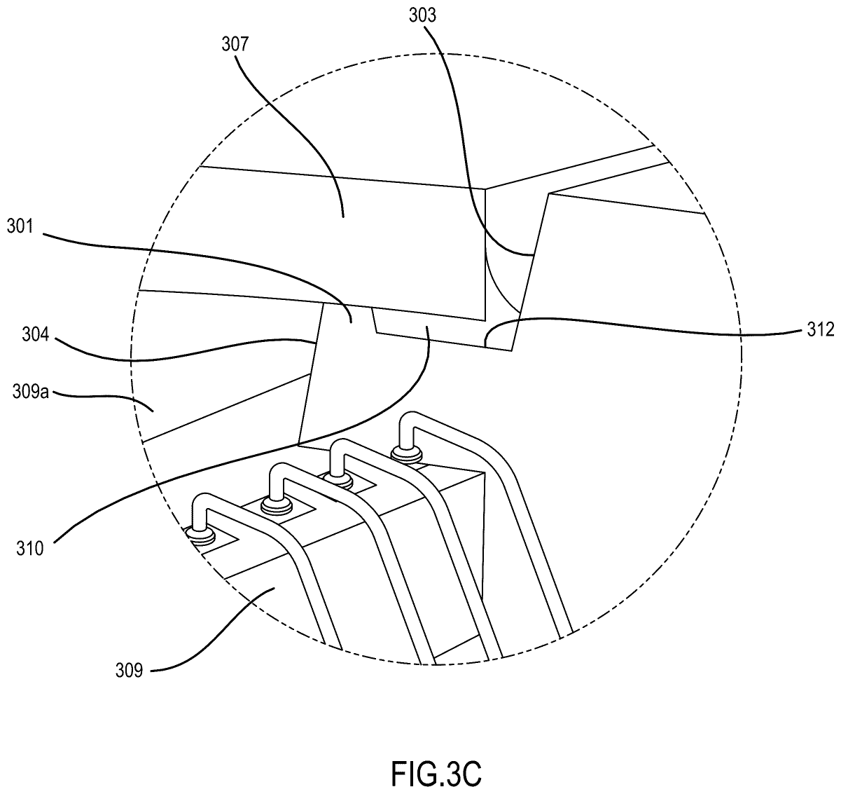

FIGS. 3A-3C show example electronic device 300, in accordance with various embodiments. In the example of FIGS. 3A-3C, electronic device 300 comprises lid 307 coupled to body 308 and positioned over electronic component 309. In some examples, body comprises or can be referred to as a molded structure. Lid 307 can comprise glass, metal, plastic, or other materials. In some examples, electronic component 309 can include, for example, micro-electromechanical system (MEMS) sensors that comprise a lidded or capped cavity. Examples of MEMS sensors can include, for example, pressure, temperature, humidity, gas, ultrasonic, or other sensors. In some examples, electronic component 309 can include a sensor region 309a. For example, electronic device 300 in the example of FIG. 3A can include optical or imaging sensors as well as other sensors responsive to electromagnetic stimuli detected via line of sight (LoS).

In accordance with various examples, body 308 can be disposed around a perimeter of electronic component 309. Body 308 can include pedestal 301. A channel or adhesive basin 302 of body 308 can be defined between pedestal 301, body sidewall 303, and channel floor 312 extending between pedestal 301 and body sidewall 303.

In various examples, body 308 includes a sensor cavity wall 304 extending downward to an upper side of electronic component 309. Sensor cavity wall 304 can define a cavity 305 over the upper side of electronic component 309. In some examples, sensor cavity wall 304 can have a height of approximately 100 μm to approximately 200 μm. A lens or lid 307 can be disposed over electronic component 309 and can contact a mating surface or upper side of pedestal 301. Adhesive material 310 (FIG. 3C) can be in and can fill or partially fill channel 302. Adhesive material 310 can contact a bottom side of lid 307 about a perimeter of lid 307 (e.g., outside of the interface between lid 307 and the upper side of pedestal 301). Adhesive material 310 can be coupled to and contact a bottom side of lid 307, a sidewall of lid 307, channel floor 312, body sidewall 303, and, in some examples, a sidewall of pedestal 301 to retain the perimeter of lid 307 in place over channel 302.

In some examples, pedestal 301 can extend continuously around an inner perimeter of channel 302. In some examples, vents can be defined between segments of pedestal 301, which can be intermittent, segmented, or spaced around the inner perimeter of channel 302. Pedestal 301 can retain adhesive material 310 and can prevent adhesive material 310 from migrating outside of channel 302. Pedestal 301 can have a height of approximately 50 μm to approximately 100 μm, as measured from channel floor 312. Pedestal 301 can have a width of approximately 50 μm to approximately 100 μm, as measured at the upper side of pedestal 301. Channel 302 can have a width of approximately 100 μm to approximately 200 μm, as measured between pedestal 301 and body sidewall 303.

In various examples, pedestal 301 around cavity 305 of electronic device 300 can function as a lid levelling mechanism. The upper side pedestal 301 can have a substantially uniform height over electronic component 309. Lid 307 can be coupled to pedestal 301 with the interface between pedestal 301 and lid 307 being substantially devoid of adhesive material 310. For example, lid can bottom out on or directly contact the upper side of pedestal 301. By bottoming out lid 307 against pedestal 301, electronic device 300 can reduce or eliminate the effect of BLT variation between pedestal 301 and lid 307. The position of pedestal 301 can also serve as flow stopper or flow control feature that inhibits the adhesive from contaminating the die area.

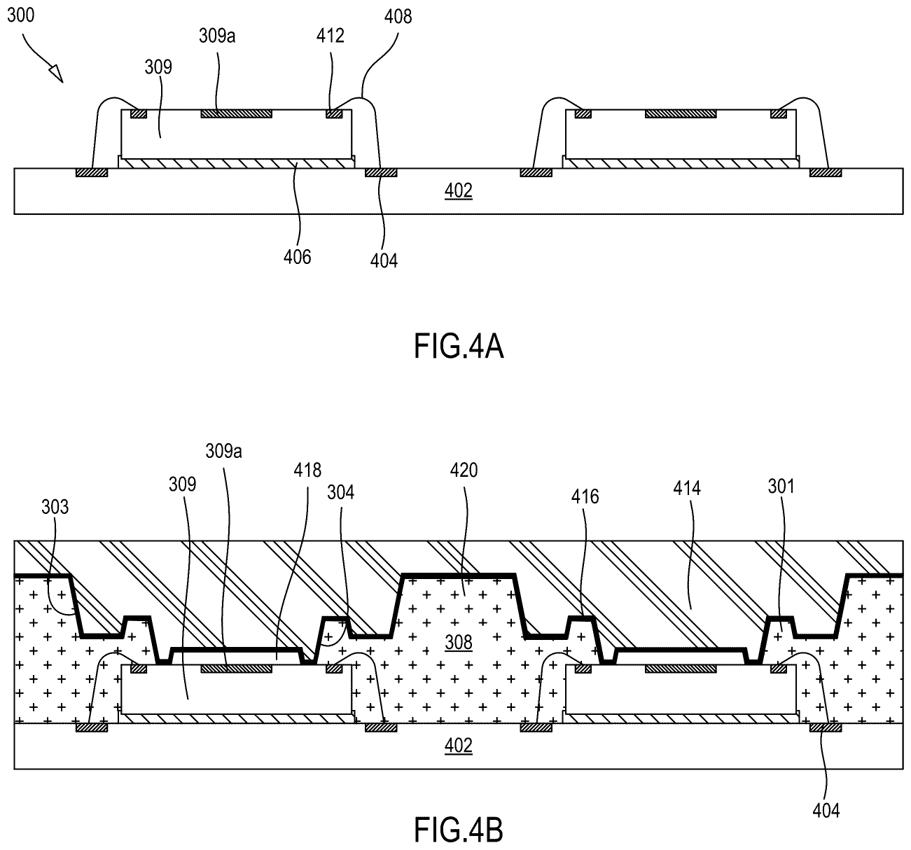

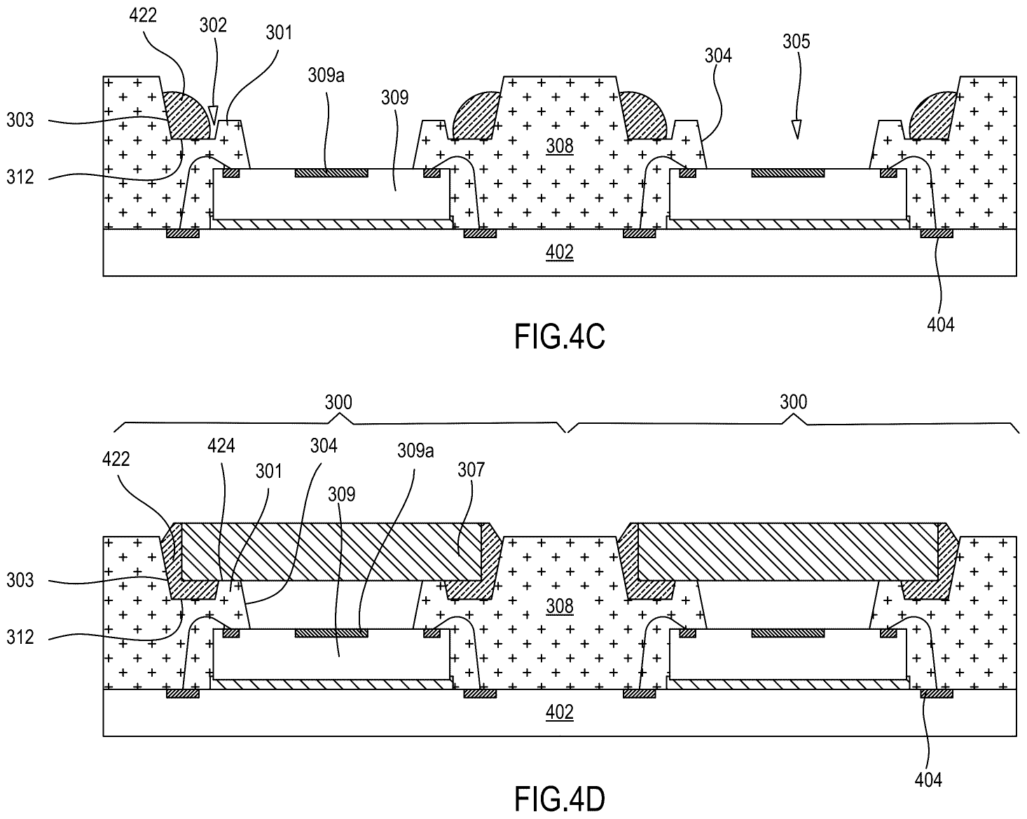

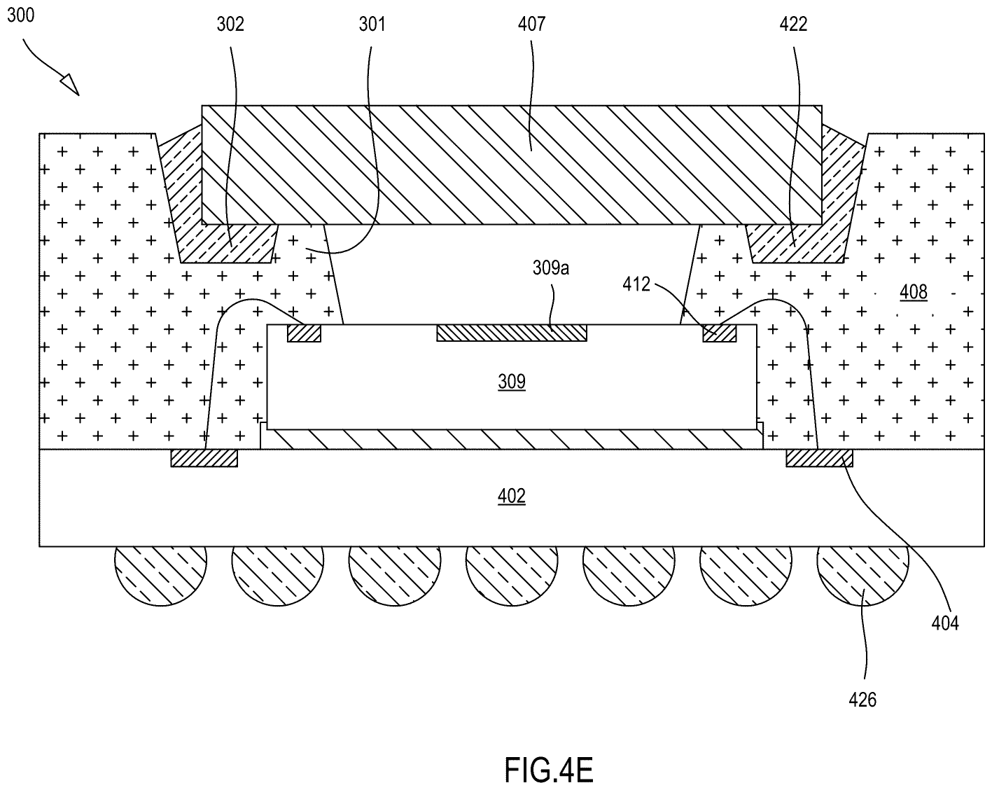

In FIGS. 4A-4D, an example method is shown for manufacturing an electronic device 300. FIG. 4A shows electronic device 300 at an early stage of manufacture. Substrate 402 can be provided. Electronic component 309 can be provided over substrate 402. Electronic component 309 can be coupled to substrate 402 by attach material 406. In some examples, attach material 406 can comprise or be referred to as an adhesive, adhesive film, or die attach film. For example, attach material 406 can be applied to the upper side of substrate 402 by dispensing or printing, and electronic component 309 can be placed on die attach material 406 so the lower side of the electronic component 309 is coupled with attach material 406. In some examples, an attach material 406 in film form can be coupled to the lower side of electronic component 309, and the lower side of electronic component 309 can be coupled to the upper side of substrate 402 through attach material 406.

In various examples, electronic component 309 can be wire bonded or otherwise electrically coupled to substrate 402. Substrate terminal 404 is coupled to component terminal 412 via interconnect 408. In the example of FIG. 4A, interconnect 408 can comprise a wire bond. Component terminal 412 and sensor region 309a can be on an upper side of electronic component 309 oriented away from or opposite substrate 402. In some examples, the elements, features, materials, or manufacturing methods of substrate 402 can be similar to, or the same as, substrate 11 in FIG. 1. In some examples, substrate 402 can comprise a wafer having a plurality of semiconductor die.

FIG. 4B shows electronic device 300 at a later stage of manufacture. In the example of FIG. 4B, mold insert 414 can be provided over electronic component 309 and substrate 402. Mold insert 414 can define an opening 418 over sensor region 309a of electronic component 309. Mold insert 414 can define body 308 in negative space. Mold insert 414 can define pedestal 301, channel 302, body sidewall 303, and sensor cavity wall 304, for example, in negative space. A molding material 420 can be provided around and under mold insert 414, between substrate 402 and mold insert 414, and between electronic component 309 and mold insert 414. Mold insert 414 may include a mold release film 416 to enable release of body 308 from mold insert 414.

Mold release film 416 can be disposed between mold insert 414 and electronic component 309. Mold material 420 can be injected, deposited, or otherwise provided into a chase or mold to form body 308. In some examples, the chase can be a carbon steel chase with resolution of approximately 100 μm. Mold material 420 can fill accessible area between mold insert 414 and substrate 402 and between mold insert 414 and electronic component 309. Mold material 420 can cover interconnects 408 and a perimeter of the upper side of electronic component 309. Opening 418 can remain devoid of mold material 420 with sensor region 309a exposed from mold material 420.

FIG. 4C shows electronic device 300 at a later stage of manufacture. In the example of FIG. 4C, mold insert 414 can be released and removed from body 308. Mold release film 416 can be removed from body 308. Adhesive material 422 can be deposited in channel 302, on a sidewall of pedestal 301, on channel floor 312, or on body sidewall 303. In the example of FIG. 4C, a bead of adhesive material 422 can be deposited in the corner joining body sidewall 303 with channel floor 312, opposite pedestal 301.

FIG. 4D shows electronic device 300 at a later stage of manufacture. In the example, of FIG. 4D, lid 307 can be provided over electronic component 309. In various examples, lid 307 can be disposed at least partially in a cavity defined by body sidewall 303. A perimeter area of lid 307 can be urged into contact with pedestal 301 at contact area or interface 424. Lid 307 can press into or displace adhesive material 422. Adhesive material 422 can translate laterally along channel floor 312 towards pedestal 301. Pedestal 301 can retain adhesive material 422 and inhibit adhesive material 422 from escaping onto sensor cavity wall 304 or onto the upper side of electronic component 309.

In various examples, adhesive material 422 can translate upwards along body sidewall 303 and around the lateral sides of lid 307. Adhesive material 422 can couple sidewalls and a lower side of lid 307 to body 308. In some examples, contact area 424 between pedestal 301 and lid 307 can be substantially devoid of adhesive material 422.

In some examples, lid 307 can be bottom out against, abut, or otherwise contact the upper side of pedestal 301. In some examples, a portion of lid 307 can be countersunk or at least partially recessed from the upper surface of body 308 (e.g., a lower side of lid 307 can be lower than the upper side of body 308). Lid 307 can be partially recessed into a lid cavity defined by body sidewalls 303 and, in some examples, an upper side of lid 307 can protrude above the upper side of body 308. In other examples, the upper side of lid 307 can be recessed from the upper side of body 308. A distance between lid 307 and electronic component 309, can be precisely controlled using body 308 and pedestal 301 to reliably locate lid 307 at a desired height over substrate 402 and electronic component 309.

FIG. 4E shows electronic device 300 at a later stage of manufacture. In the example of FIG. 4E, external interconnects 426 can be provided. External interconnect 426 can comprise or be referred to as a bump, pad, or pillar. In some examples, external interconnects 426 can be coupled to or contact outer terminals of substrate 402, similar to external interconnects 101 and outer terminal 113b in FIG. 2F. One or more conductive structures of substrate 402 (e.g., traces, vias, etc.) can electrically couple external interconnects 426 and substrate terminals 404. In various examples, electronic devices 300 can be laser marked. After providing external interconnects 426 a singulation process can be performed to separate individual electronic devices 300. In various examples, electronic device 300 can include a sensor package with a cavity-pedestal design for leveling and flow control.

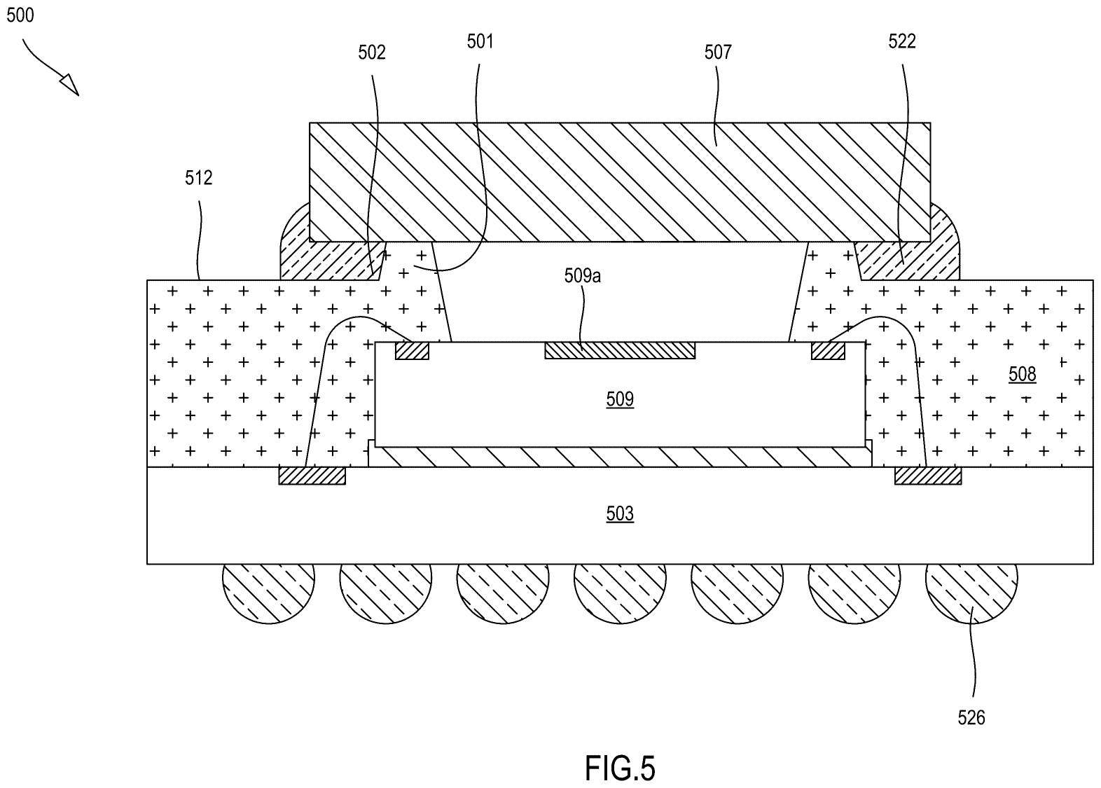

FIG. 5 shows example electronic device 500. Electronic device 500 in the example of FIG. 5 can be similar to electronic device 300 described above. Electronic device 500 can include body 508 with pedestal 501 protruding above upper side 512 of body 508. Upper side 512 can be substantially flat in the region adjacent pedestal 501. A bead of adhesive material 522 can be provided in corner 502 between pedestal 501 and upper side 512 for retention on the outer side of pedestal 501. Lid 507 can be urged into contact with pedestal 501. The interface between lid 507 and the upper side of pedestal 501 can be substantially devoice of adhesive material 522. Lid 507 can be coupled to body 508 by adhesive material 522. Lid 507 can be positioned above upper side 512, electronic component 509, and substrate 503 by pedestal 501. Pedestal 501 can retain adhesive material 522 and prevent adhesive material 522 from translating onto the upper side of electronic component 509, and also precisely position lid 507 over electronic component 509 and/or sensor region 509a.

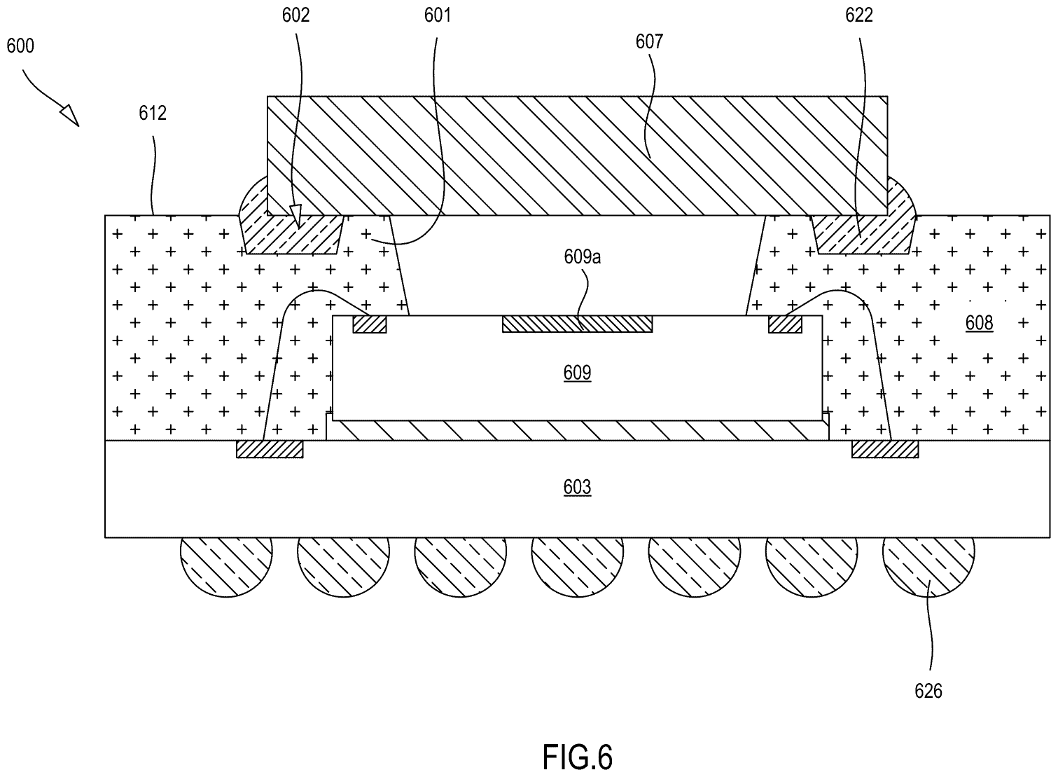

FIG. 6 shows an example electronic device 600. Electronic device 600 in the example of FIG. 6 can be similar to electronic device 300 described above. Electronic device 600 can include body 608 including pedestal 601. An upper side of pedestal 601 can be substantially coplanar with upper side 612 of body 608. Body 608 can define channel 602. Channel 602 can be provided in upper side 612. A floor of channel 602 can be recessed with respect to upper side 612 and the upper side of pedestal 601. Upper side 612 can be substantially flat in the region adjacent channel 602. Channel 602 can receive adhesive material 622. A bead of adhesive material 622 can be provided in channel 602 between pedestal 601 and upper side 612. Lid 607 can be urged into contact with pedestal 601 with lateral sides of lid 607 terminating over channel 602. Lid 607 can be coupled to body 608 by adhesive material 622. The interface between lid 607 and the upper side of pedestal 601 can be substantially devoid of adhesive material 622. Lid 607 can be positioned above body 608, electronic component 609, and substrate 603 by pedestal 601. External interconnects 626 can be coupled to substrate 603. Pedestal 601 can retain adhesive material 622 and prevent adhesive material 622 translating out of channel 602 towards the upper side of electronic component 609. Pedestal 601 can also precisely position lid 607 over electronic component 609 and/or sensor region 609a.

In various examples, a body or molded structure can include a pedestal comprising an upper side configured to receive or contact a lens or lid. The upper side of the pedestal can be sized and configured to locate the lens at a desired distance above a sensor or other electronic component. An adhesive can be deposited adjacent the pedestal and can contact the lid to retain the lens in place at a desired distance over the electronic component. The pedestal can reduce an impact of variable BLT in achieving the desired height of the lens over the electronic component.

Various examples can achieve lower package height by embedding the lid into the lid cavity defined by the body sidewall. Electronic devices of the present disclosure can reduce cost due to smaller lid and minimal material to attach the lid. Lid planarity can be improved in various embodiments by utilizing the pedestal height as levelling mechanism. Quality can be improved by the adhesive-blocking effect of the pedestal and lid contacting one another, limiting the potential contamination of the die area with overflow attach material. Various examples include a channel adjacent a pedestal to have improved seal quality with the lid attach material flowing away from the pedestal, creating fillets on lid edges.

The present disclosure includes reference to certain examples; however, it will be understood by those skilled in the art that various changes can be made and equivalents may be substituted without departing from the scope of the disclosure. Modifications may be made to the disclosed examples without departing from the scope of the present disclosure. Therefore, it is intended that the present disclosure not be limited to the examples disclosed, but that the disclosure will include all examples falling within the scope of the appended claims.

What is claimed:

1. An electronic device, comprising:
a substrate including a cavity defined in an upper side of the substrate;
an electronic component disposed over the substrate;
a lid disposed over the substrate and including a lid stopper in the cavity, a pedestal over the electronic component, and a channel adjacent the pedestal; and
a lens disposed over the electronic component and on the pedestal.

2. The electronic device of claim 1, further comprising:
a first adhesive in the cavity; and
a second adhesive in the channel.

3. The electronic device of claim 2, wherein the lid stopper contacts a floor of the cavity.

4. The electronic device of claim 3, wherein the lens contacts the pedestal.

5. The electronic device of claim 4, wherein the second adhesive contacts a bottom side of the lens outside an interface between the lens and the pedestal.

6. The electronic device of claim 4, wherein the first adhesive is between a sidewall of the lid and a sidewall of the substrate that defines the cavity.

7. The electronic device of claim 4, wherein an interface between the pedestal and the lens is substantially devoid of the second adhesive.

8. The electronic device of claim 4, wherein an interface between the stopper of the lid and the floor of the cavity is substantially devoid of the first adhesive.

9. The electronic device of claim 1, wherein the channel is defined by a lid sidewall, a sidewall of the pedestal, and channel floor extending between the lid sidewall and the sidewall of the pedestal, and wherein the lens is spaced apart from the lid sidewall and channel floor.

10. The electronic device of claim 1, wherein the electronic component comprises a sensor region.

11. The electronic device of claim 1, wherein the electronic component comprises a sensor application-specific integrated circuit (ASIC).

12. The electronic device of claim 1, wherein the electronic component comprises a micro-electromechanical system (MEMS) device.

13. A method of manufacturing an electronic device, comprising:
providing a lid including a stopper on a lower side of the lid, a pedestal having an upper side oriented away from the lower side of the lid, and a channel adjacent the pedestal;
providing a first adhesive in the channel;
providing a lens over the first adhesive and contacting the pedestal;
coupling an electronic component to an upper side of a substrate; and
providing the lid over the substrate, wherein the stopper is located in a cavity formed in the upper side of the substrate and the lens is over the electronic component.

14. The method of claim 13, further comprising providing a second adhesive in the cavity.

15. The method of claim 14, wherein the stopper contacts a floor of the cavity, and an interface between the stopper and the floor of the cavity is substantially devoid of the second adhesive.

16. An electronic device, comprising:
a substrate;
an electronic component disposed over the substrate and comprising a sensor region oriented away from the substrate;
a body disposed over the substrate and around the electronic component, the body including a pedestal and a channel adjacent the pedestal, wherein the sensor region of the electronic component is exposed from the body; and
a lens disposed over the electronic component and on the pedestal.

17. The electronic device of claim 16, further comprising an adhesive disposed in the channel.

18. The electronic device of claim 17, wherein an interface between the lens and the pedestal is substantially devoid of the adhesive.

19. The electronic device of claim 16, wherein a bottom side of the lens contacts the pedestal.

20. The electronic device of claim 16, wherein an upper side of the pedestal is recessed relative to an upper side of the body.
